(19) United States
(12) Patent Application Publication
(10) Pub. No.: US 2025/0237956 A1
(43) Pub. Date: Jul. 24, 2025

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Yongsik YOO, Suwon-si (KR); Younhee Nam, Suwon-si (KR); Yoona Kim, Suwon-si (KR); Donghoon Won, Suwon-si (KR); Won Jong Hwang, Suwon-si (KR); Taesoo Kim, Suwon-si (KR); Seunghyun Kim, Suwon-si (KR); Jooyoung Chung, Suwon-si (KR)

(21) Appl. No.: 19/010,356

(22) Filed: Jan. 6, 2025

(30) Foreign Application Priority Data
Jan. 24, 2024 (KR) 10-2024-0010864

(51) Int. Cl. G03F 7/20

(52) U.S. Cl. CPC G03F 7/2016

(57) ABSTRACT

A hardmask layer including a cured product of the hardmask composition, and a method of forming patterns that uses the hardmask layer including a cured product of the hardmask composition, the hardmask composition includes a polymer including a structural unit represented by Chemical Formula 1; and a solvent,

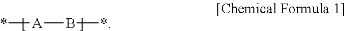

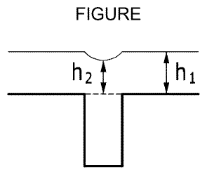

### CROSS-REFERENCE TO RELATED APPLICATION

This application claims priority to and the benefit of Korean Patent Application No. 10-2024-0010864 filed in the Korean Intellectual Property Office on Jan. 24, 2024, the entire contents of which are incorporated herein by reference.

### BACKGROUND

### 1. Field

Embodiments relate to a hardmask composition, a hardmask layer including a cured product of the hardmask composition, and a method of forming a pattern using the hardmask composition.

### 2. Description of the Related Art

Recently, the semiconductor industry has developed an ultra-fine technique having a pattern of several to several tens nanometer size. Such ultrafine techniques may use effective lithographic techniques.

Some lithographic techniques may include providing a material layer on a semiconductor substrate; coating a photoresist layer thereon; exposing and developing the same to provide a photoresist pattern; and etching a material layer using the photoresist pattern as a mask.

### SUMMARY

Embodiments are directed to a hardmask composition, including a polymer including a structural unit represented by Chemical Formula 1; and a solvent,

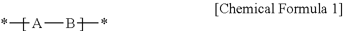

wherein, in Chemical Formula 1, A is a substituted or unsubstituted C6 to C30 aromatic hydrocarbon ring or a ring assembly group of two or more substituted or unsubstituted C6 to C30 aromatic rings linked by a single bond or a substituted or unsubstituted C1 to C10 alkylene group, B is a group represented by Chemical Formula 2, and * is a linking point,

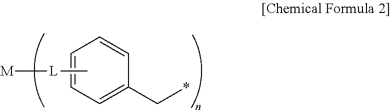

wherein, in Chemical Formula 2, M is a substituted or unsubstituted C1 to C40 hydrocarbon group, L is a single bond, —O—, —S—, —N—, a substituted or unsubstituted C1 to C10 alkylene group, or a combination thereof, n is an integer greater than or equal to 3, and * is a linking point.

A may include a substituted or unsubstituted moiety of Group 1.

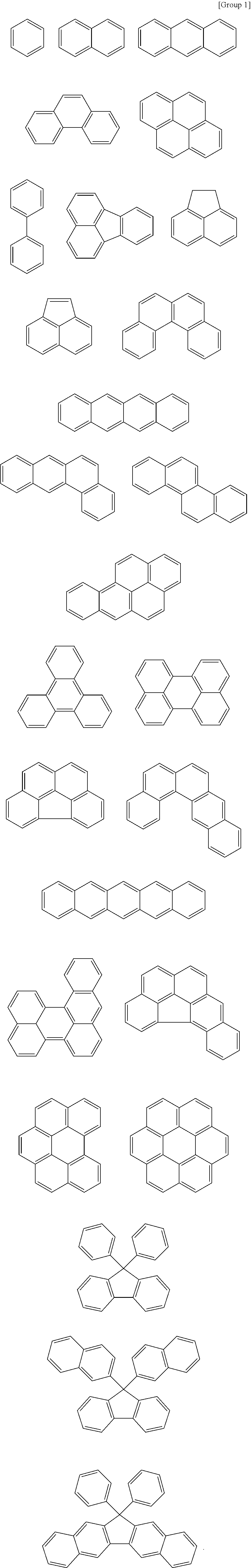

M may be a trivalent or tetravalent substituted or unsubstituted C1 to C30 saturated or unsaturated aliphatic hydrocarbon group, a substituted or unsubstituted C6 to C30 aromatic ring, or a ring assembly group of two or more substituted or unsubstituted C6 to C20 aromatic rings linked by a single bond or a substituted or unsubstituted C1 to C10 alkylene group.

In Chemical Formula 2, M may be a hydrocarbon group of Group 2, in which * is a linking point, L may be —O—, and n may be an integer of 3 or 4,

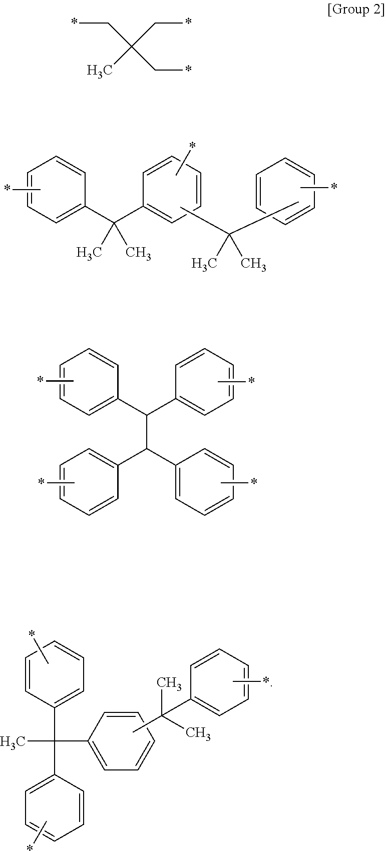

The polymer may further include a structural unit represented by Chemical Formula 3,

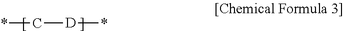

in Chemical Formula 3, C may be a substituted or unsubstituted moiety of Group 3, D may be a divalent organic group of Group 4, and * is a linking point,

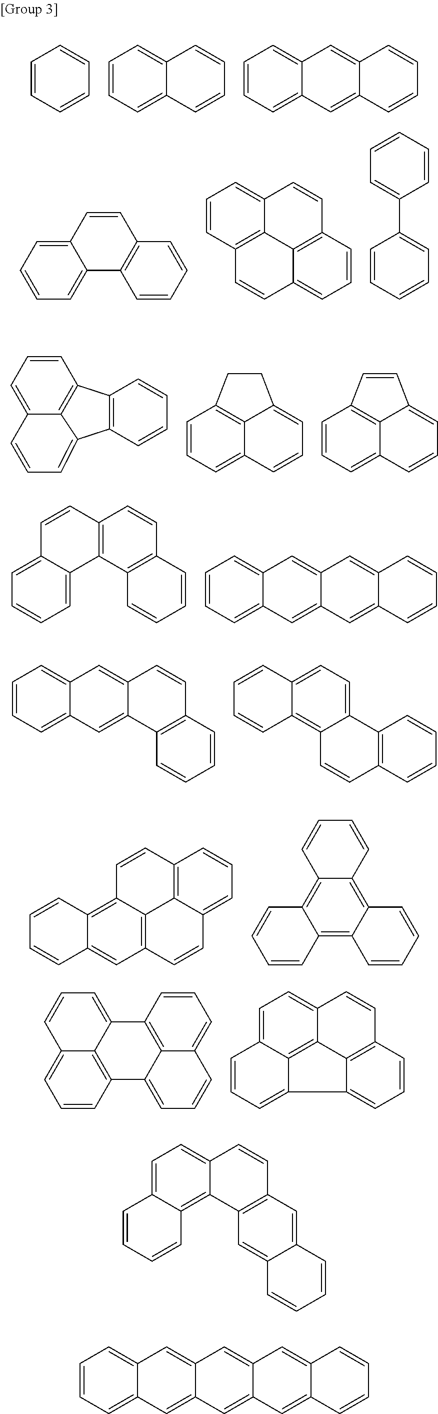

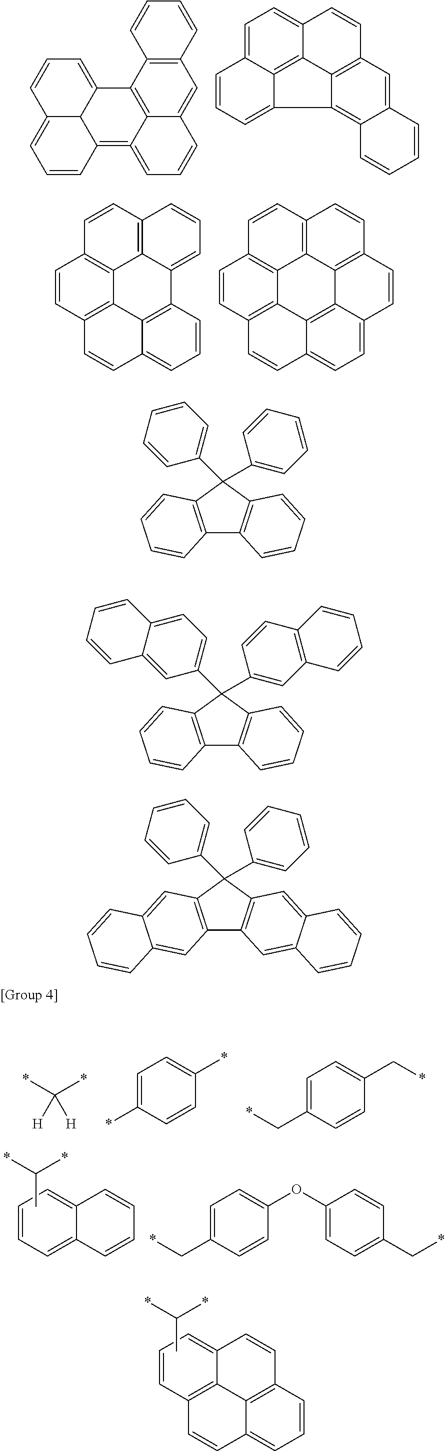

in Group 4, * is a linking point.

Chemical Formula 1 may be represented by one of Chemical Formula 1-1 to Chemical Formula 1-5, in which * is a linking point,

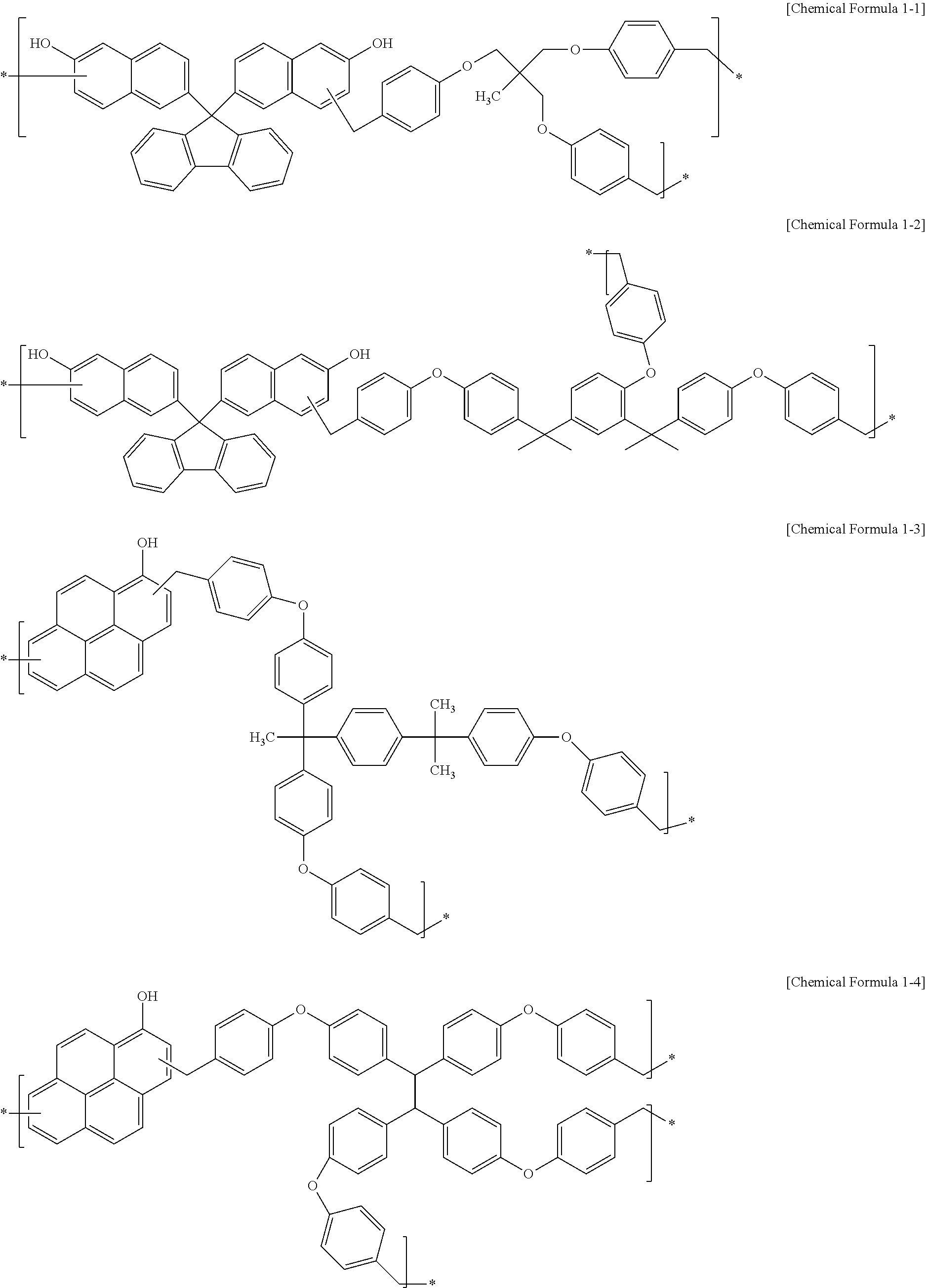

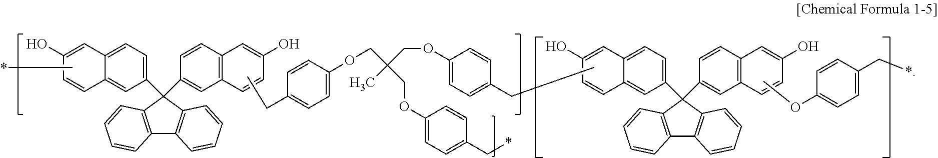

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

The embodiments may be realized by providing a hardmask layer including a cured product of the hardmask composition according to an embodiment.

The embodiments may be realized by providing a method of forming patterns, the method including providing a material layer on a substrate; applying the hardmask composition to the material layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

The heat-treating may be performed at about 100° C. to about 1,000° C.

### BRIEF DESCRIPTION OF THE DRAWING

Features will become apparent to those of skill in the art by describing in detail exemplary embodiments with reference to the attached drawing in which:

The FIGURE a reference diagram illustrating a step difference of a hardmask layer to explain a method of evaluating planarization characteristics.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not necessarily an exclusive term, e.g., “A or B” would include A, B, or A and B. As used herein, hydrogen substitution (—H) may include deuterium substitution (-D) or tritium substitution (-T). For example, any hydrogen in any compound described herein may be protium, deuterium, or tritium (e.g., based on natural or artificial substitution).

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon ring” refers to a group including at least one hydrocarbon aromatic moiety, and includes a form in which hydrocarbon aromatic moieties are linked by a single bond, a non-aromatic fused ring form in which hydrocarbon aromatic moieties are fused directly or indirectly, or a combination thereof as well as a non-fused aromatic hydrocarbon ring or a condensed aromatic hydrocarbon ring.

More specifically, the substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a substituted or unsubstituted fluorenyl group, a combination thereof, or a combined fused ring of the foregoing groups, but is not limited thereto.

As used herein, when a definition is not otherwise provided, “combination” means mixing or copolymerization.

As used herein, when a definition is not otherwise provided, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

In the semiconductor industry, a size of chips may be reduced. Accordingly, the line width of the resist patterned in lithography technology may be tens of nanometers in size. A height that can withstand the line width of the resist pattern may be limited, and the resist may not have sufficient resistance in the etching step. In order to compensate for this, an auxiliary layer, which is called a hardmask layer, may be used between a material layer to be etched and a photoresist layer. Because this hardmask layer may serve as an interlayer that transfers the fine pattern of the photoresist to the material layer through selective etching, the hardmask layer may exhibit heat resistance and etch resistance to withstand the etching process required for pattern transfer. In addition, in cases where there is a step in the substrate to be processed in a multiple patterning process, or if a region with dense patterns and a region without a pattern exist together on the wafer, the hardmask layer filled with the pattern may exhibit planarization characteristics that minimize a step difference between patterns.

Some other hardmask layers may be formed in a chemical or physical deposition method and may have low economic efficiency due to a large-scale equipment and a high process cost. Therefore, a method of forming a hardmask layer by a spin-coating technique has recently been considered. The spin-coating technique may be easier to process than other methods and in addition, may help secure excellent gap-fill characteristics and planarization characteristics of a hardmask layer formed therefrom. Accordingly, it may be a hardmask composition to which spin-coating techniques can be applied. In a hardmask layer formed using the spin-coating technique, the required etch resistance could be somewhat lowered. Accordingly, a hardmask composition according to an embodiment may be applied using the spin-coating technique and may secure equivalent etch resistance to that of the hardmask layer formed in the chemical or physical deposition method.

In order to help improve the etch resistance of the hardmask layer, maximizing a carbon content of a hardmask composition may be considered. However, as a carbon content of a polymer included in the hardmask composition is maximized, solubility in solvents could decrease. According to an embodiment, the carbon content maximization of a polymer included in the hardmask composition may not only improve the etch resistance of the hardmask layer formed of the hardmask composition but may also help secure high solubility of the polymer in the solvents.

The hardmask composition according to some embodiments may include a polymer including a structural unit represented by Chemical Formula 1, and a solvent.

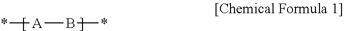

A may be or include, e.g., a substituted or unsubstituted C6 to C30 aromatic hydrocarbon ring, or a ring assembly group of two or more substituted or unsubstituted C6 to C30 aromatic rings linked by a single bond or a substituted or unsubstituted C1 to C10 alkylene group.

B may be a group represented by Chemical Formula 2.

* is a linking point.

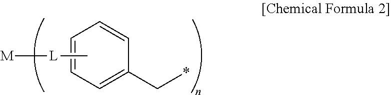

In Chemical Formula 2, M may be or include, e.g., a substituted or unsubstituted C1 to C40 hydrocarbon group.

L may be or include, e.g., a single bond, —O—, —S—, —N—, a substituted or unsubstituted C1 to C10 alkylene group, or a combination thereof.

n may be an integer greater than or equal to 3.

* is a linking point.

The composition according to some embodiments may help increase a carbon content in the composition by including an aromatic ring or a ring assembly group including two or more aromatic rings in the structural unit of the polymer. Accordingly, the etch resistance of the hardmask layer formed from the composition including the polymer may be secured.

In addition, the structural unit may include a linking group represented by Chemical Formula 2 and may form a branched structure in the polymer, through which a crosslinked structure between the polymers may be formed. Accordingly, the polymer may have a denser structure, and a hardmask layer formed from a composition including the polymer may secure excellent heat resistance. In addition, the linking group represented by Chemical Formula 2 may help provide flexibility to the polymer, help increase its solubility in solvents, and help ensure excellent gap-fill characteristics.

In Chemical Formula 1, A may be or include a substituted or unsubstituted moiety of Group 1.

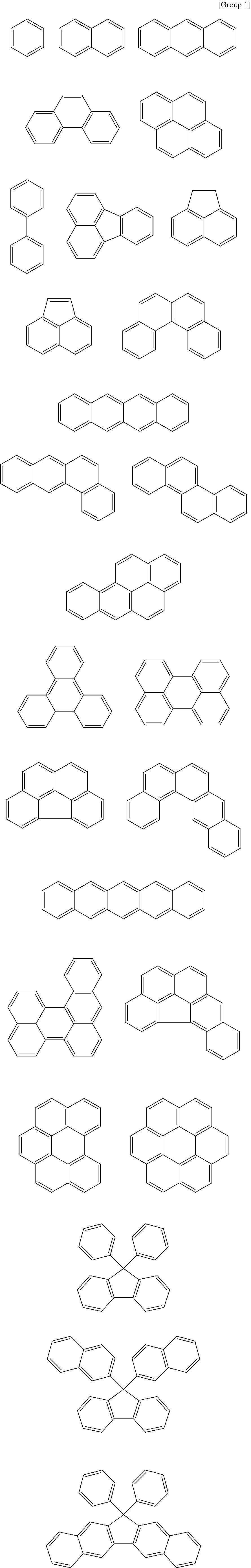

In Chemical Formula 2, M may be, e.g., a trivalent or tetravalent substituted or unsubstituted C1 to C30 saturated or unsaturated aliphatic hydrocarbon group, a substituted or unsubstituted C6 to C30 aromatic ring or a ring assembly group of two or more substituted or unsubstituted C6 to C20 aromatic rings linked by a single bond or a substituted or unsubstituted C1 to C10 alkylene group. In an implementation, M may be a trivalent or tetravalent substituted or unsubstituted C1 to C10 saturated or unsaturated aliphatic hydrocarbon group or a ring assembly group of two or more substituted or unsubstituted C6 to C20 aromatic rings linked by a single bond, or a substituted or unsubstituted C1 to C5 alkylene group.

In an implementation, M of Chemical Formula 2 may be a hydrocarbon group of Group 2.

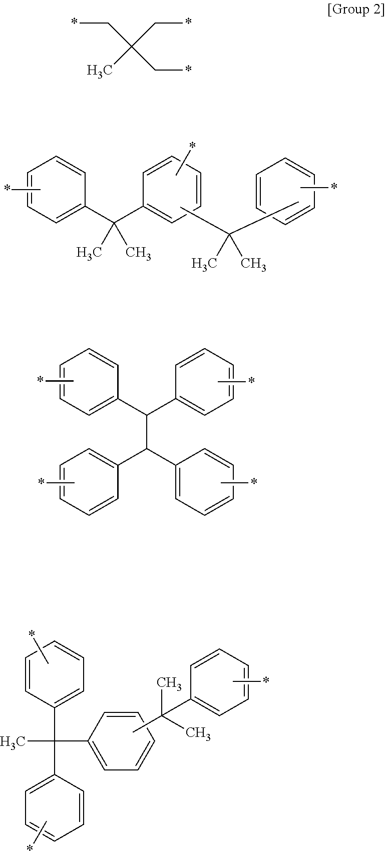

In Group 2, * is a linking point.

In Chemical Formula 2, L may be, e.g., a single bond, —O—, —S—, —N—, a substituted or unsubstituted C1 to C5 alkylene group, or a combination thereof, a single bond, —O—, a substituted or unsubstituted C1 to C5 alkylene group, or a combination thereof, or —O—. If L is —O—, —S—, or —N—, solubility of the polymer in the solvent may be further increased.

In Chemical Formula 2, n may be an integer greater than or equal to 3 that does not exceed a bond valency of M. For example, if M was a phenyl group, n may be an integer of 3 to 6. If n is an integer of greater than or equal to 3, the polymer including the linking group represented by Chemical Formula 2 may have branched structure, through which crosslinks between polymers may be formed, and the structure of the polymer including the same may become more dense. In an implementation, n may be an integer of 3 to 6, e.g., 3 or 4.

In Chemical Formula 2, * is a linking point to A in the same structural unit or A in another structural unit.

In an implementation, the polymer may further include a structural unit represented by Chemical Formula 3.

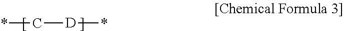

In Chemical Formula 3, C may be or include, e.g., a substituted or unsubstituted moiety of Group 3.

D may be or include, e.g., a divalent organic group of Group 4.

* is a linking point.

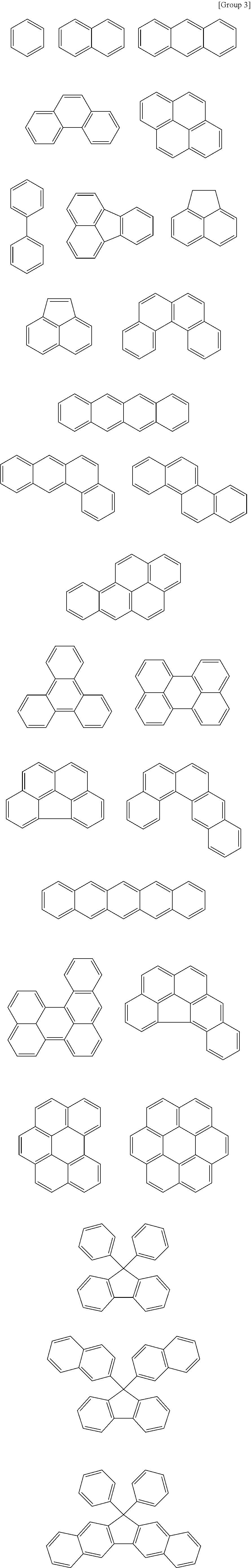

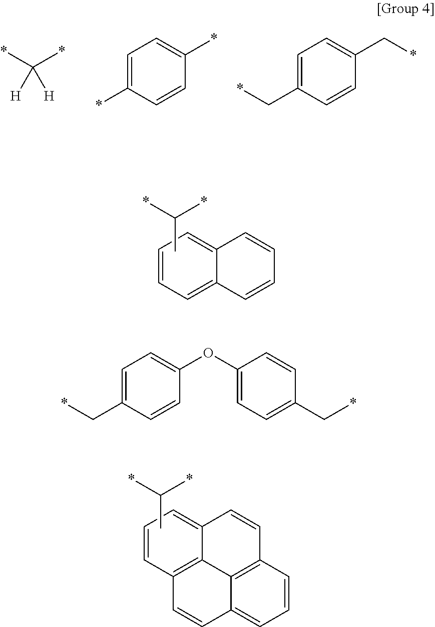

In Group 4, * is a linking point.

By further including the structural unit represented by Chemical Formula 3, the polymer may help increase the carbon content in the polymer and may help further improve the etch resistance of the hardmask layer formed from a composition including it.

In an implementation, Chemical Formula 1 may be expressed as one of Chemical Formula 1-1 to Chemical Formula 1-5.

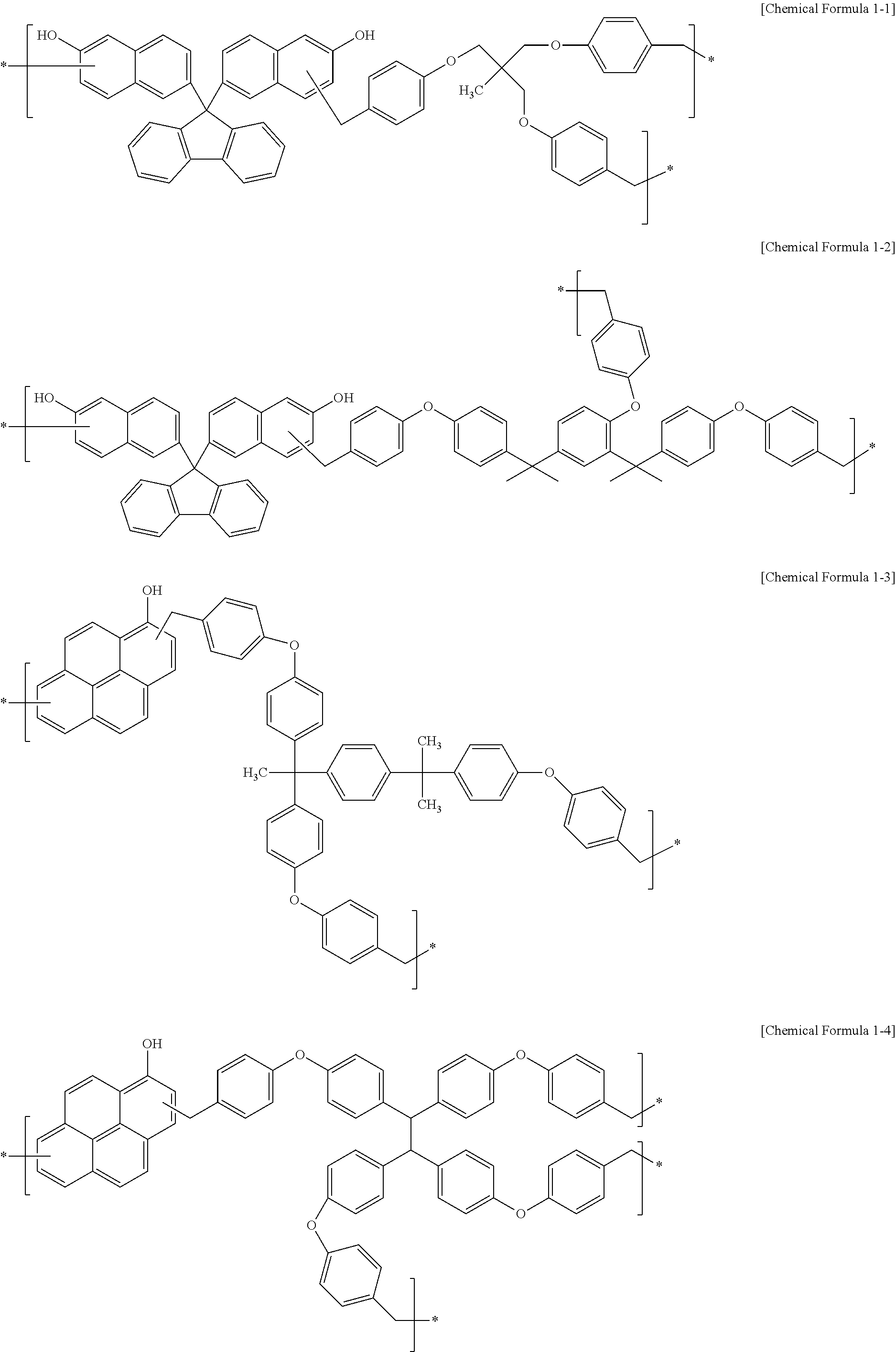

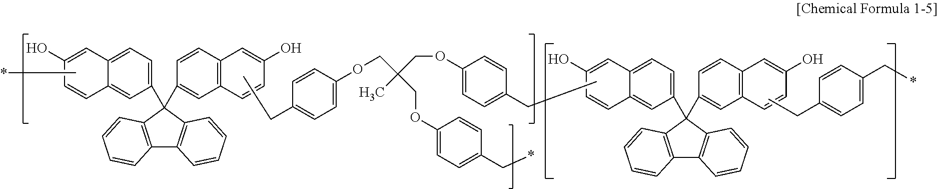

The polymer may have a weight average molecular weight of about 1,000 g/mol to about 200,000 g/mol. In an implementation, the polymer may have a weight average molecular weight of about 1,000 g/mol to about 150,000 g/mol, about 1,000 g/mol to about 100,000 g/mol, about 1,200 g/mol to about 50,000 g/mol, or about 1,200 g/mol to about 10,000 g/mol. Maintaining the weight average molecular weight within the above ranges may help ensure that the carbon content and solubility in the solvent of the hardmask composition including the above polymer may be adjusted and optimized.

In an implementation, the polymer may be included in an amount of, e.g., about 0.1 wt % to about 30 wt %, based on a total weight of the hardmask composition. In an implementation, the polymer may be included in an amount of about 0.2 wt % to about 30 wt %, e.g., about 0.5 wt % to about 30 wt %, about 1 wt % to about 30 wt %, about 1.5 wt % to about 25 wt %, or about 2 wt % to about 20 wt %. Maintaining the amount of the polymer within the above ranges may help ensure that a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, N-methyl-2-pyrrolidone, acetylacetone, ethyl 3-ethoxypropionate, or the like. In an implementation the solvent may include a suitable solvent, as long as it has sufficient solubility or dispersibility with respect to the polymer.

In an implementation, the hardmask composition may further include an additive, e.g., a surfactant, a crosslinking agent, a thermal acid generator, or a plasticizer.

The surfactant may include, e.g., a fluoroalkyl compound, alkylbenzenesulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

In an implementation, the thermal acid generator may include an acid compound, e.g., p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include, e.g., providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer and a copper layer, a semiconductor layer such as a silicon layer, or an insulating layer such as a silicon oxide layer and a silicon nitride layer. The material layer may be formed through, e.g., a chemical vapor deposition (CVD) process.

The hardmask composition may be the same as described above, and may be applied by spin-on coating in a form of a solution. In an implementation, an application thickness of the hardmask composition may be, e.g., 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour. In an implementation, the heat-treating may be performed under an atmosphere of air or nitrogen, or an atmosphere having an oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, e.g., about 30 seconds to about 30 minutes, about 30 seconds to about 10 minutes, or about 30 seconds to about 5 minutes.

In an implementation, the heat-treating may include a second heat-treating process that may be consecutively performed, e.g., at about 100° C. to about 1,000° C., about 300° C. to about 1,000° C., about 500° C. to about 1,000° C., or about 500° C. to about 600° C. for about 30 seconds to about 1 hour, e.g., about 30 seconds to about 30 minutes, about 30 seconds to about 10 minutes, or about 30 seconds to 5 minutes. In an implementation, the first and second heat-treating processes may be performed under an air or nitrogen atmosphere, or may be performed under an atmosphere with an oxygen concentration of about 1 wt % or less.

By performing at least one of the steps of heat-treating the hardmask composition at a high temperature of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include at least one of a first heat-treating process, a second heat-treating process, a UV/Vis curing process, and a near IR curing process, or may include two or more processes consecutively.

In an implementation, the method may further include forming a silicon-containing thin layer on the hardmask layer. The silicon-containing thin layer may be formed of, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas. In an implementation, the etching gas may include, e.g., N₂/O₂, CHF₃, CF₄, Cl₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Compound

### Synthesis Example 1

4-hyroxybenzaldehyde (40.3 g, 0.33 mol), 1,3-dibromo-2-(bromomethyl)-2-methylpropane (30.6 g, 0.1 mol), potassium carbonate (82.9 g, 0.6 mol), and 400 ml of anhydrous dimethylformamide (DMF) were added to a flask and then, stirred under a nitrogen flow at 100° C. for 14 hours.

After a reaction was completed, the reactant was cooled to ambient temperature and slowly added dropwise to 1,000 ml of cold water. A solid produced therein was filtered, twice washed with 500 ml of water, and washed with a methanol aqueous solution (200 ml of water:MeOH=3:1), and the remaining solvent was removed under a reduced pressure to obtain Compound 1a represented by Chemical Formula 1a.

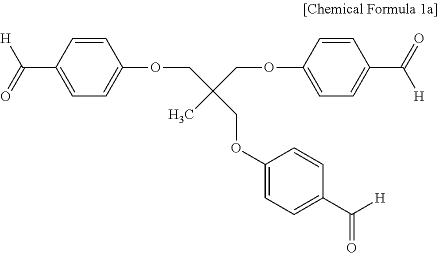 [SMILES: CC(COc1ccc(C=O)cc1)(COc1ccc(C=O)cc1)COc1ccc(C=O)cc1]

Compound 1a (43.2 g, 0.1 mol) was dissolved in 500 ml of dichloromethane:MeOH=1:1, and sodium borohydride (34 g, 0.9 mol) was slowly added thereto at ambient temperature over 20 minutes and then, stirred at ambient temperature for 5 hours.

After a reaction was completed, after removing about a half of the solvent under a reduced pressure, an organic layer was extracted with 600 ml of ethyl acetate, and the remaining solvent was removed therefrom under a reduced pressure to obtain Compound 1b represented by Chemical Formula 1b.

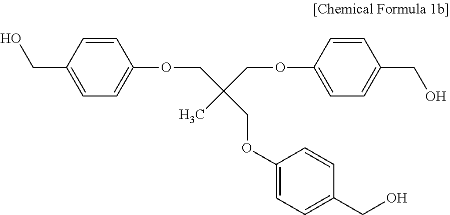 [SMILES: CC(COc1ccc(CO)cc1)(COc1ccc(CO)cc1)COc1ccc(CO)cc1]

Compound 1b (21.9 g, 0.05 mol) was dissolved in 150 ml of anhydrous dimethylformamide (DMF), and sodium hydride (12 g, 0.5 mol) was slowly added thereto, while blowing nitrogen, and then, additionally stirred at ambient temperature for 30 minutes. Subsequently, Iodomethane (71 g, 0.5 mol) was slowly added in a dropwise fashion to the reactant and then, additionally stirred at ambient temperature for 3 hours.

After a reaction was completed, an organic layer was extracted therefrom with 500 ml of ethyl acetate, and the remaining solvent was removed under a reduced pressure and treated through column chromatography to obtain Compound 1c represented by Chemical Formula 1c.

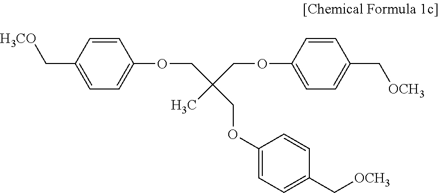 [SMILES: COCc1ccc(OCC(C)(COc2ccc(COC)cc2)COc2ccc(COC)cc2)cc1]

### Synthesis Example 2

Compound 2c represented by Chemical Formula 2c was obtained in the same manner as in Synthesis Example 1 except that 4-fluorobenzaldehyde was used instead of the 4-hyroxybenzaldehyde and also, 2,4-bis[2-(4-hydroxyphenyl)-2-propanyl]phenol instead of the 1,3-dibromo-2-(bromomethyl)-2-methylpropane was used.

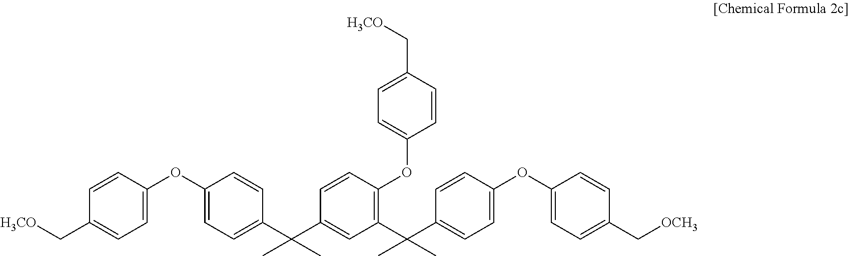 [SMILES: COCc1ccc(Oc2ccc(C(C)(C)c3ccc(Oc4ccc(COC)cc4)c(C(C)(C)c4ccc(Oc5ccc(COC)cc5)cc4)c3)cc2)cc1]

### Synthesis Example 3

Compound 3c represented by Chemical Formula 3c was obtained in the same manner as in Synthesis Example 2 except that 4,4′-(1-(4-(2-(4-hydroxyphenyl)propan-2-yl)phenyl)ethane-1,1-diyl)diphenol instead of the 2,4-bis[2-(4-hydroxyphenyl)-2-propanyl]phenol was used.

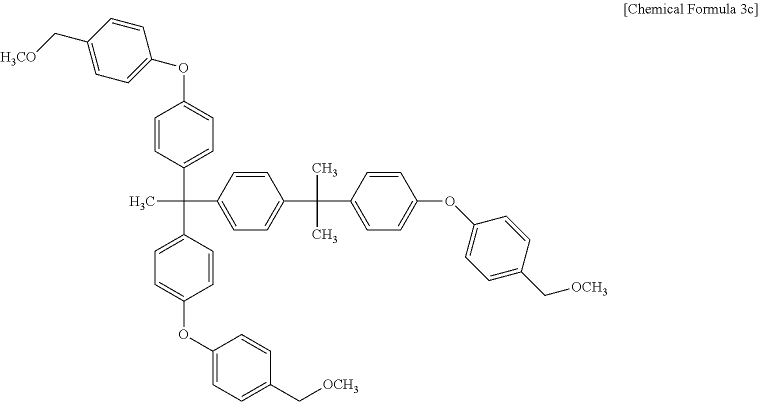 [SMILES: COCc1ccc(Oc2ccc(C(C)(C)c3ccc(C(C)(c4ccc(Oc5ccc(COC)cc5)cc4)c4ccc(Oc5ccc(COC)cc5)cc4)cc3)cc2)cc1]

### Synthesis Example 4

Compound 4c represented by Chemical Formula 4c was obtained in the same manner as in Synthesis Example 2 except that 1,1,2,2-tetrakis(p-hydroxyphenyl)ethane instead of the 2,4-bis[2-(4-hydroxyphenyl)-2-propanyl]phenol was used.

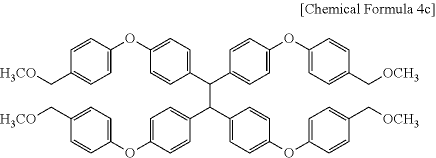 [SMILES: COCc1ccc(Oc2ccc(C(c3ccc(Oc4ccc(COC)cc4)cc3)C(c3ccc(Oc4ccc(COC)cc4)cc3)c3ccc(Oc4ccc(COC)cc4)cc3)cc2)cc1]

### Synthesis of Polymers

### Polymerization Example 1

9,9-bis(6-hydroxy-2-naphthyl)fluorene (22.5 g, 0.05 mol), Compound 1c (15.8 g, 0.033 mol), diethyl sulfate (0.15 g), and propylene glycolmonomethyl ether acetate (PGMEA, 150 g) were sequentially added to a flask and then, polymerized by stirring at 90° C. for 6 hours.

After a reaction was completed, the reactant was added to 50 g of distilled water and 200 g of methanol and then, vigorously stirred and allowed to stand. Subsequently, after removing a supernatant therefrom, precipitates were dissolved in 60 g of PGMEA and then, vigorously stirred by using 200 g of methanol. The purification process was repeated 5 times, and then, the purified polymer was dissolved in 100 g of PGMEA, and the remaining solvent was removed under a reduced pressure to obtain Polymer 1 having a weight average molecular weight of 2,500 g/mol and including a structural unit represented by Chemical Formula 1-1.

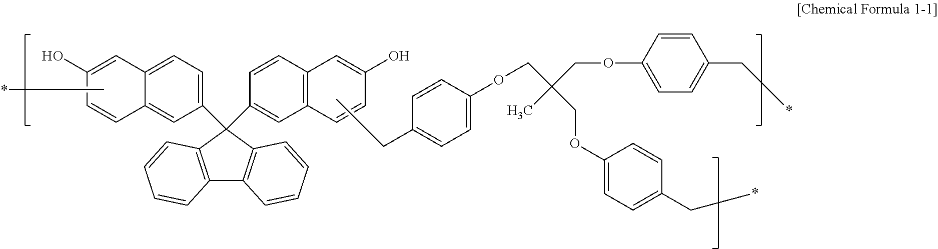

### Polymerization Example 2

Polymer 2 having a weight average molecular weight of 2,500 g/mol and including a structural unit represented by Chemical Formula 1-2 was obtained in the same manner as in Polymerization Example 1 except that Compound 2c was used instead of Compound 1c.

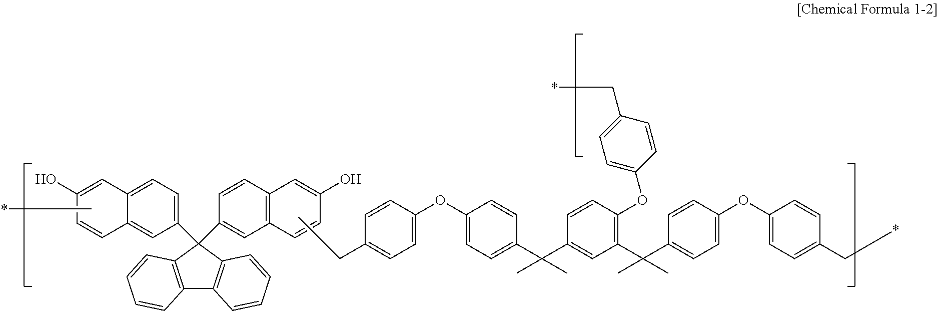

### Polymerization Example 3

Polymer 3 having a weight average molecular weight of 2,500 g/mol and including a structural unit represented by Chemical Formula 1-3 was obtained in the same manner as in Polymerization Example 1 except that 1-hydroxy pyrene instead of the 9,9-bis(6-hydroxy-2-naphthyl)fluorene and also, Compound 3c instead of Compound 1c were used.

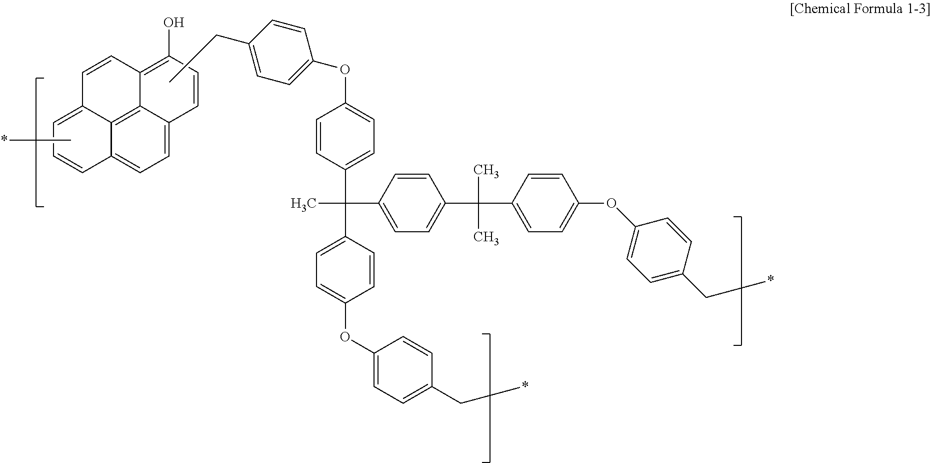

### Polymerization Example 4

Polymer 4 having a weight average molecular weight of 2,500 g/mol and including a structural unit represented by Chemical Formula 1-4 was obtained in the same manner as in Polymerization Example 3 except that Compound 4c was used instead of Compound 1c.

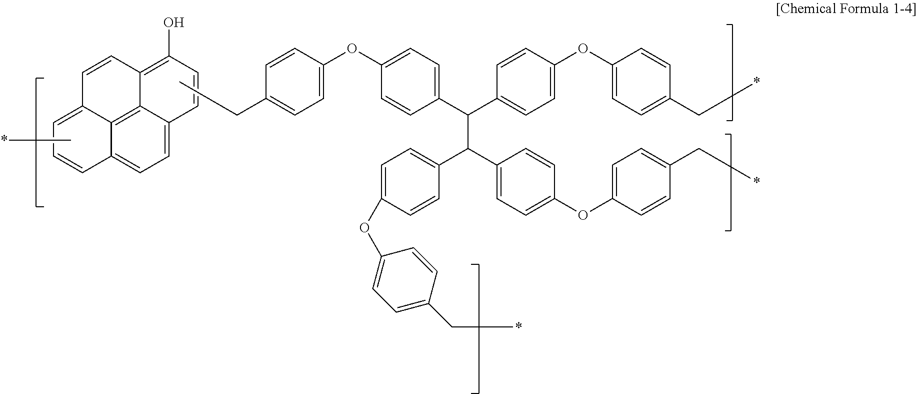

### Polymerization Example 5

9,9-bis(6-hydroxy-2-naphthyl)fluorene (22.5 g, 0.05 mol), Compound 1c (9.6 g, 0.02 mol), diethyl sulfate (0.15 g), and PGMEA (150 g) were sequentially added to a flask and polymerized by stirring at 90° C. for 2 hours. Subsequently, 1,4-bis(methoxymethyl)benzene (3.3 g, 0.02 mol) was added thereto and then, stirred for 4 hours.

After a reaction was completed, the reactant was added to 50 g of distilled water and 200 g of methanol and then, vigorously stirred and allowed to stand. Subsequently, after removing a supernatant therefrom, precipitates were dissolved in 60 g of PGMEA and then, vigorously stirred by 200 g of methanol and allowed to stand. The purification process was repeated two times, and then, the purified polymer was dissolved in 100 g of PGMEA, and the remaining solvent was removed under a reduced pressure to obtain Polymer 5 having a weight average molecular weight of 2,500 g/mol and including a structural unit represented by Chemical Formula 1-5.

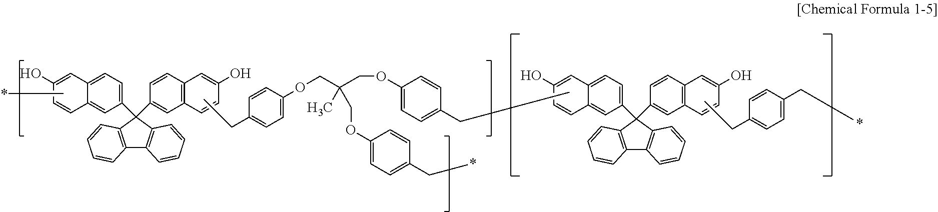

### Comparative Polymerization Example 1

9,99,9-bis(6-hydroxy-2-naphthyl)fluorene (22.5 g, 0.05 mol) and paraformaldehyde (1.5 g, 0.05 mol) were added to a flask, and 0.57 g (0.003 mol) of p-toluene sulfonic acid monohydrate was dissolved in 163 g of PGMEA and then, polymerized by stirring at 90° C. for 15 hours.

After a reaction was completed, the reactant was added to 40 g of distilled water and 300 g of methanol and then, vigorously stirred and allowed to stand. Subsequently, after removing a supernatant therefrom, precipitates therein were dissolved in 80 g of PGMEA and then, vigorously stirred by using 300 g of methanol and allowed to stand. This purification process was repeated 5 times, and the purified polymer was dissolved in 100 g of PGMEA, and the remaining methanol and distilled water were removed under a reduced pressure to obtain Comparative Polymer 1 having a weight average molecular weight of 2,500 g/mol and including a structural unit represented by Chemical Formula X.

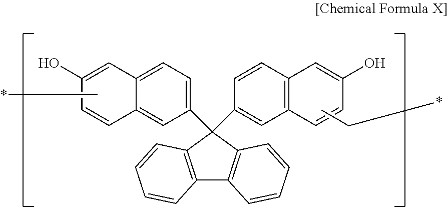

### Comparative Polymerization Example 2

Comparative Polymer 2 having a weight average molecular weight of 2,500 g/mol and including a structural unit represented by Chemical Formula Y was obtained in the same manner as in Comparative Polymerization Example 1 except that 1-hydroxypyrene instead of the 9,9-bis(6-hydroxy-2-naphthyl)fluorene and also, 1,4-bis(methoxymethyl)benzene instead of the paraformaldehyde were used.

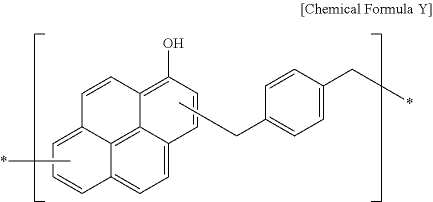

### Preparation of Hardmask Compositions

### Examples 1-1 to 5-1 and Comparative Examples 1-1 and 2-1

Each of the polymers according to Polymerization Examples 1 to 5 and Comparative Polymerization Examples 1 to 2 was, respectively, uniformly dissolved in a mixed solvent of PGMEA and cyclohexanone in a volume ratio of 1:1 to prepare a hardmask composition having a solid content of about 15 wt %.

### Examples 1-2 to 5-2 and Comparative Examples 1-2 and 2-2

Each hardmask composition with a solid content of about 5 to 10 wt % was prepared by, respectively, uniformly dissolving each polymer according to Polymerization Examples 1 to 5 and Comparative Polymerization Examples 1 to 2 in a mixed solvent of PGMEA and cyclohexanone in a volume ratio of 1:1.

### Evaluation 1: Evaluation of Heat Resistance

Each of the hardmask compositions according to Examples 1-1 to 5-1 and Comparative Examples 1-1 to 2-1 was coated on a silicon wafer and then, heat-treated on a hot plate at 150° C. for 2 minutes to form a hardmask film. The hardmask film was evaluated with respect to heat resistance under an air temperature-increasing condition by using a thermogravimetric analyzer (TGA), and the results are shown in Table 1. In Table 1, T₉₅ (° C.) is a temperature that a residual weight of the hardmask film was 95% of its initial weight, and T₉₀ (° C.) is a temperature that a residual weight of the hardmask film was 90% of its initial weight.

TABLE 1

| | T₉₅ (° C.) | T₉₀ (° C.) |
|---|---|---|
| Example 1-1 | 405 | 427 |
| Example 2-1 | 401 | 429 |
| Example 3-1 | 410 | 438 |
| Example 4-1 | 415 | 431 |
| Example 5-1 | 407 | 420 |
| Comparative Example 1-1 | 375 | 397 |
| Comparative Example 2-1 | 382 | 398 |

Referring to Table 1, the hardmasks formed of the compositions according to the examples exhibited higher T₉₅ and T₉₀ than those of hardmasks formed of the compositions according to the comparative examples. Accordingly, the hardmask compositions of the examples exhibited improved heat resistance, compared with the hardmask compositions of the comparative examples.

### Evaluation 2: Evaluation of Planarization and Gap-fill Characteristics

Each of the hardmask compositions of Examples 1-2 to 5-2 and Comparative Examples 1-2 to 2-2 was coated on a patterned wafer (an aspect ratio=1:2) and heat-treated on a hot plate at 400° C. for 2 minutes to form a 2,000 Δ to 2,100 Δ-thick thin film to evaluate gap-fill characteristics and planarization performance by using an electron scanning microscope (SEM).

The gap-fill characteristics were evaluated by examining a cross-section of each thin film pattern with a scanning electron microscope (SEM) to determine whether or not a void was generated. The planarization characteristics were evaluated from a resulting value of Calculation Equation 1 regarding a planarization degree (%). Referring to the FIGURE, h₁ of Calculation Equation 1 is an average thickness of a thin film at any three points on a portion of a substrate with no pattern, and h₂ is another average thickness of the thin film at any three points on a portion of the substrate with a pattern. The thin film thickness was measured by using a thin film thickness meter made by K-MAC, and as the following planarization degree was larger, planarization characteristics were more excellent. The gap-fill characteristics and planarization characteristics results are shown in Table 2.

$$Planarization degree ( \% ) = {h}_{2} / {h}_{1} \times 100 ( \% ) \qquad [ Calculation Equation 1 ]$$

TABLE 2

| | Planarization | Voids are present |
|---|---|---|
| | degree (%) | or absent |
| Example 1-2 | 74 | Voids are absent |
| Example 2-2 | 77 | Voids are absent |
| Example 3-2 | 89 | Voids are absent |
| Example 4-2 | 72 | Voids are absent |
| Example 5-2 | 79 | Voids are absent |
| Comparative Example 1-2 | 52 | Voids are present |
| Comparative Example 2-2 | 55 | Voids are present |

Referring to Table 2, the hardmask layers formed of the hardmask compositions according to the examples, compared with the hardmask layers formed of the hardmask compositions according to the comparative examples, exhibited excellent planarization characteristics and gap-fill characteristics.

By way of summation and review, according to small-sizing the pattern to be formed, it could be difficult to provide a fine pattern having an excellent profile by using only some lithographic techniques. Accordingly, an auxiliary layer, called a hardmask layer, may be formed between the material layer and the photoresist layer to provide a fine pattern.

A hardmask layer formed from the hardmask composition according to some embodiments may help secure excellent heat resistance.

A hardmask layer formed from the hardmask composition according to some embodiments may help secure excellent gap-fill characteristics and planarization characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent, 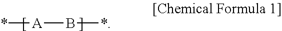
wherein, in Chemical Formula 1,
A is a substituted or unsubstituted C6 to C30 aromatic hydrocarbon ring or a ring assembly group of two or more substituted or unsubstituted C6 to C30 aromatic rings linked by a single bond or a substituted or unsubstituted C1 to C10 alkylene group,
B is a group represented by Chemical Formula 2, and
* is a linking point, 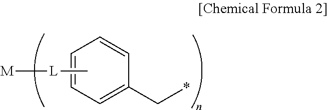
wherein, in Chemical Formula 2,
M is a substituted or unsubstituted C1 to C40 hydrocarbon group,
L is a single bond, —O—, —S—, —N—, a substituted or unsubstituted C1 to C10 alkylene group, or a combination thereof,
n is an integer greater than or equal to 3, and
* is a linking point.

2. The hardmask composition as claimed in claim 1, wherein A includes a substituted or unsubstituted moiety of Group 1,

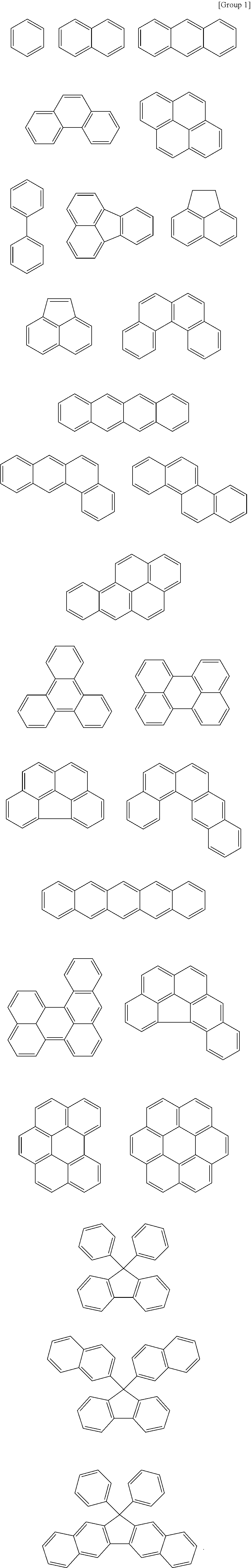

3. The hardmask composition as claimed in claim 1, wherein M is a trivalent or tetravalent substituted or unsubstituted C1 to C30 saturated or unsaturated aliphatic hydrocarbon group, a substituted or unsubstituted C6 to C30 aromatic ring, or a ring assembly group of two or more substituted or unsubstituted C6 to C20 aromatic rings linked by a single bond or a substituted or unsubstituted C1 to C10 alkylene group.

4. The hardmask composition as claimed in claim 1, wherein in Chemical Formula 2:
M is a hydrocarbon group of Group 2, in which * is a linking point,
L is —O—, and
n is an integer of 3 or 4,

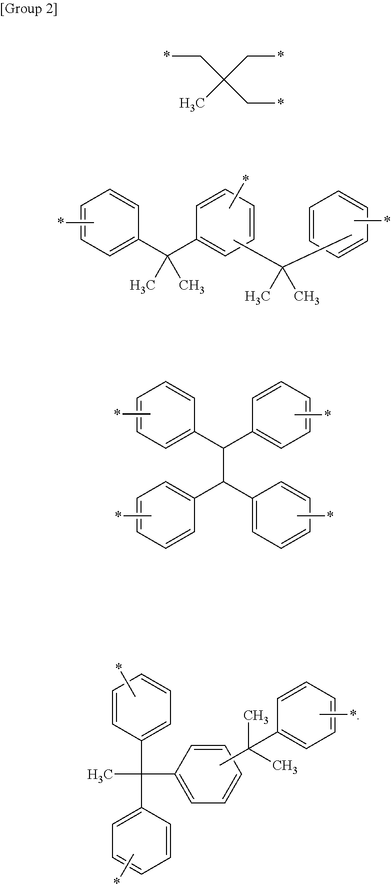

5. The hardmask composition as claimed in claim 1, wherein:
the polymer further includes a structural unit represented by Chemical Formula 3, 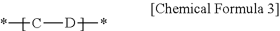
in Chemical Formula 3,
C is a substituted or unsubstituted moiety of Group 3,
D is a divalent organic group of Group 4, and
* is a linking point, 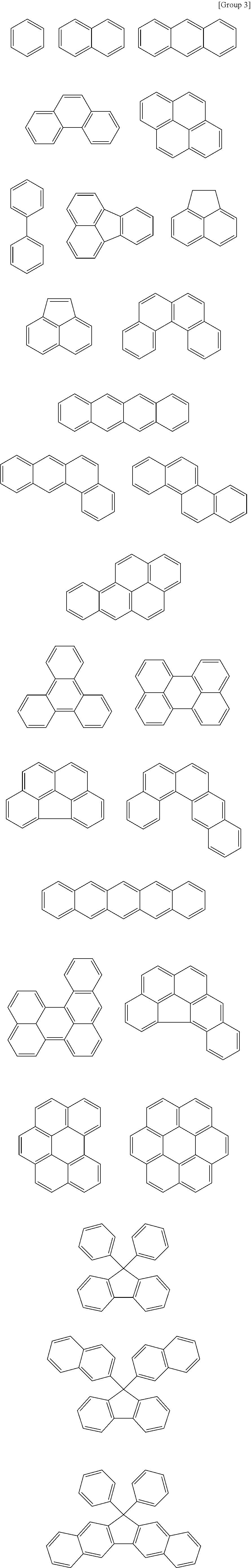 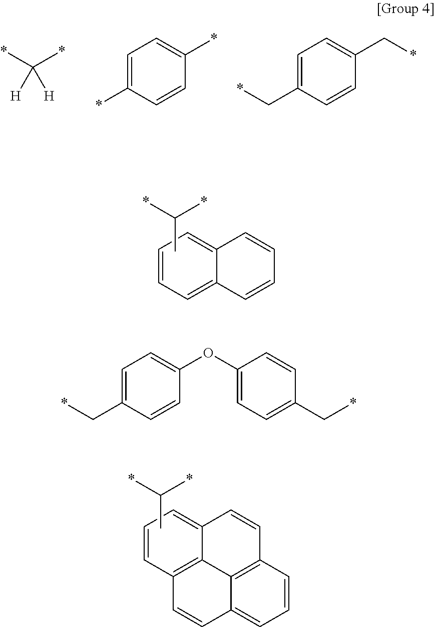
in Group 4, * is a linking point.

6. The hardmask composition as claimed in claim 1, wherein Chemical Formula 1 is represented by one of Chemical Formula 1-1 to Chemical Formula 1-5, in which * is a linking point,

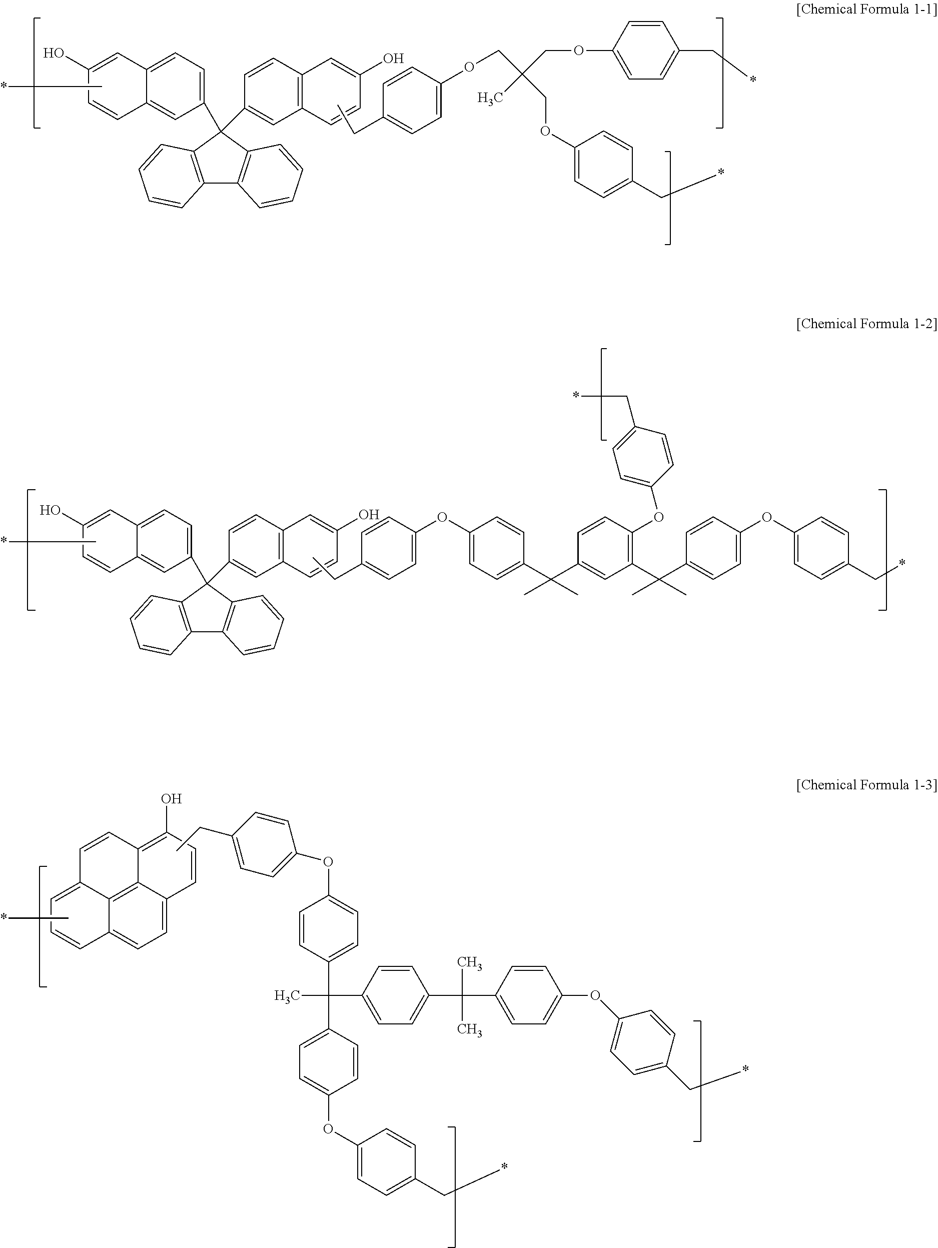

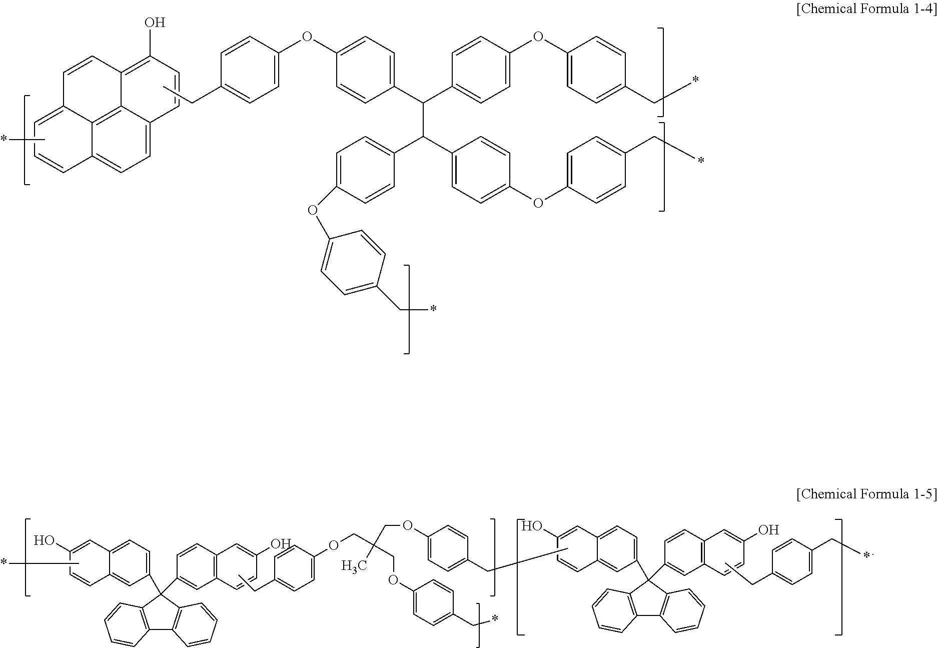

7. The hardmask composition as claimed in claim 1, wherein the polymer has a weight average molecular weight of about 1,000 g/mol to about 200,000 g/mol.

8. The hardmask composition as claimed in claim 1, wherein the polymer is included in an amount of about 0.1 wt % to about 30 wt %, based on a total weight of the hardmask composition.

9. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, N-methyl-2-pyrrolidone, acetylacetone, or ethyl 3-ethoxypropionate.

10. A hardmask layer comprising a cured product of the hardmask composition as claimed in claim 1.

11. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

12. The method as claimed in claim 11, wherein the heat-treating is performed at about 100° C. to about 1,000° C.
